(19) United States
(12) Patent Application Publication
(10) Pub. No.: US 2007/0014975 A1
(43) Pub. Date: Jan. 18, 2007

(54) Method of manufacturing wiring substrate, and wiring substrate

(75) Inventor: Hiroshi Ota, Ashigara-Kami-Gun (JP)

Correspondence Address: BIRCH STEWART KOLASCH & BIRCH, PO BOX 747, FALLS CHURCH, VA, 22040-0747, US

(73) Assignee: FUJI PHOTO FILM CO., LTD.

(21) Appl. No.: 11/485,428

(22) Filed: Jul. 13, 2006

(30) Foreign Application Priority Data
Jul. 14, 2005 (JP) 2005-205621

(51) Int. Cl. B05D 5/12; B05D 7/00; H05K 3/00; B32B 3/00

(52) U.S. Cl. 428/209; 427/532; 427/212; 427/97.7

(57) ABSTRACT

The method of manufacturing a wiring substrate comprises the steps of: performing a pattern exposure of a resin layer containing photocatalyst particles, in a shape of a desired wiring pattern so that the photocatalyst particles are exposed at a surface of the resin layer; performing irradiation of radiation to the resin layer having the exposed photocatalyst particles while the resin layer having the exposed photocatalyst particles is immersed in an aqueous solution of a metallic salt so that a photochemical reduction and precipitating of a metal film onto the exposed photocatalyst particles are performed; and forming a conducting layer on the metal film.

### BACKGROUND OF THE INVENTION

1. Field of the Invention

The present invention relates to a wiring substrate and a method of manufacturing a wiring substrate, and more particularly, to a wiring substrate and a method of manufacturing a wiring substrate where the adhesion between a resin layer forming a supporting substrate and a conductive layer forming a wiring conductor is improved without using harmful substances, and a high-density arrangement of very fine wires can be achieved.

2. Description of the Related Art

In recent years, there has been a tendency for the various electronic components which are used in electronic devices to be integrated at higher density, in accordance with reductions in the weight and size of these electronic devices. In response to this, the wiring patterns of the wiring substrate on which the various electronic components are mounted is formed to higher density, and very fine dimensions of the order of approximately 10 μm, for instance, are required for the width of the wiring patterns, and the intervals between the patterns. The bonding surface area between a wiring conductor (conducting layer) formed to an extremely fine size in this way, and a supporting substrate (resin layer) for this wiring conductor, tend to become extremely small, and hence the bonding force between the conducting layer and the resin layer, in other words, the adhesion between these layers, declines.

For example, Japanese Patent Application Publication No. 2-205388 discloses a technique whereby a coupling agent containing a semiconducting photocatalyst powder is deposited in a pattern on the surface of a non-conducting material (e.g., a resin substrate, as shown in Japanese Patent Application Publication No. 2-205388), whereupon a metal plating is formed on the surface of the photocatalyst deposited on the pattern, by irradiating ultraviolet light during immersion in an aqueous solution of metallic ions containing a reducing agent, thereby creating a conducting layer.

In the method of manufacturing a printed circuit substrate described in Japanese Patent Application Publication No. 2-205388, pad printing, screen printing, and drawing by means of an X-Y plotter with dispenser attachment, are given as embodiments of methods for patterning the coupling agent containing semiconducting photocatalyst powder; however, with these methods, it is difficult to achieve high density of the very fine regions (very fine wires) in terms of accuracy.

Furthermore, the formaldehyde used in the step of forming a copper coating to form a conducting layer is a harmful substance which clearly has a detrimental effect on the natural environment, and therefore, it is not desirable to use such a substance.

Moreover, if the width of the wiring patterns is reduced in accordance with increasing miniaturization of the wiring patterns, then the thickness of the wiring patterns is also reduced, and therefore the wiring resistance (wiring impedance) increases.

### SUMMARY OF THE INVENTION

The present invention is conceived in view of the aforementioned circumstances, an object thereof being to provide a wiring substrate and a method of manufacturing a wiring substrate, whereby the bonding reliability and adhesion between a wiring conductor (conducting layer) and a supporting substrate (resin layer) can be improved, high density of the wiring patterns can be achieved, and the use of harmful substances, such as formaldehyde, are avoided in the manufacturing process.

In order to attain the aforementioned object, the present invention is directed to a method of manufacturing a wiring substrate, comprising the steps of: performing a pattern exposure of a resin layer containing photocatalyst particles, in a shape of a desired wiring pattern so that the photocatalyst particles are exposed at a surface of the resin layer; performing irradiation of radiation to the resin layer having the exposed photocatalyst particles while the resin layer having the exposed photocatalyst particles is immersed in an aqueous solution of a metallic salt so that a photochemical reduction and precipitating of a metal film onto the exposed photocatalyst particles are performed; and forming a conducting layer on the metal film.

According to this aspect of the present invention, a resin layer containing photocatalyst particles is exposed in the shape of a prescribed wiring pattern, thereby exposing the photocatalyst particles at the surface of the resin layer. Hence, exposed portions of the photocatalyst particles which correspond to a wiring pattern are formed by a photocatalytic reaction, and consequently, it is possible to achieve high-density arrangement of the wiring pattern, and to improve the dimensional accuracy during formation of the exposed portions. Furthermore, it is also possible to simplify the manufacturing step, in comparison with a step where a photocatalyst is fixed on (applied to) the surface of the resin layer.

Moreover, the method also includes the photochemical (optical) reduction precipitation step of photochemical (optical) reducing and precipitating a metal film onto the exposed portions of the photocatalyst particles by irradiating radiation while the resin layer containing exposed photocatalyst particles is immersed in an aqueous solution of a metallic salt, and the electroplating step of forming a conducting layer on this metal film.

In general, it is known that a filler is added to resin with the aim of improving the mechanical properties (for example, the strength) and the thermal properties (for example, the coefficient of expansion) of the resin. Similarly, in the field of electronics, a filler is added to the resin layer at a weight percent (ratio) of approximately 70%, with the aim of improving the thermal conductivity, reducing the coefficient of thermal expansion, and improving the strength of the resin.

In the present invention, the same material may serve both as the filler for improving the strength of the base resin and the photocatalyst for creating a photocatalytic reaction. In other words, after exposing the photocatalyst by decomposing the resin layer in a pattern shape by means of a photocatalytic reaction of the photocatalytic particles, the metal ions in the aqueous solution are reduced and precipitated onto the photocatalyst particles by means of a photocatalytic reaction of the photocatalytic particles. Therefore, since the filler for improving the resin properties also serves as a so-called plating starter material (plating initiator), then it is possible to reduce the manufacturing costs in comparison with a case where a filler material is separately added.

Here, although the exposed photocatalyst particles cause surface roughness or undulations on the surface of the resin layer, the conducting layer (or the precipitated metal film) can adapt its shape and be deposited densely in order to absorb (compensate) these indentations. Therefore, the contact surface area between the resin layer and the conducting layer is increased, and consequently, improvement in the adhesion, in other words, improvement in the bonding strength between the resin layer and the conducting layer, can be expected. Consequently, it is possible to improve the adhesion between the resin layer and the metal film, in comparison with the related art technologies in which the photocatalyst particles are patterned onto the surface of the resin layer.

Furthermore, since this method does not employ processes which are generally used in the step of bonding a conducting layer with a resin layer, such as “bonding by heating”, “bonding by pressurization”, “bonding by heating and pressurization”, “bonding by means of a bonding material, such as an adhesive”, and the like, then it is possible to simplify the manufacturing process. Moreover, it is possible to form the metal film without using harmful substances, such as formaldehyde.

In addition, the step of providing a surface roughness on the bonding surfaces of the resin layer and the conducting layer, as carried out conventionally in order to improve adhesion between the resin layer and the conducting layer, can be omitted.

Here, desirably, a process for adapting the photocatalyst particles to the resin material of the resin layer is carried out. Accordingly, the resin can be formed evenly about the whole perimeter of the photocatalyst particles, and when the resin layer is molded, then it is possible to prevent the photocatalyst particles from being exposed previously at the surface of the resin layer. This processing of the photocatalyst particles may be achieved by adjusting the properties of the actual material of the photocatalyst particles, and the processing may be separately applied to the surface of the photocatalyst particles only.

Desirably, a metal material which is similar to the metal film precipitated by the photochemical reduction precipitation step is used as the material of the conducting layer; however, it is also possible to use a different metal material from the metal film.

If the aqueous solution of metallic salt is a solution which contains copper ions, or the like, as used generally in plating wires, then the copper ions in the aqueous solution are reduced and precipitated, and hence copper is precipitated as the metal film. Furthermore, ultraviolet light, or the like, namely, light having a wavelength of 400 nm or less, is used as the radiation.

Preferably, the step of photocatalyst particle exposure includes the steps of: forming a pattern groove corresponding to substantially the same pattern as the wiring pattern, in the resin layer; and exposing the photocatalyst particles at a surface of an inner wall of the pattern groove.

According to this aspect of the present invention, a groove structure formed by a pattern groove is provided in the resin layer. Therefore, if a conducting layer (or a precipitated metal film) is formed in the groove, then the accuracy of the dimensions of formation of the conducting layer is improved, and furthermore, the adhesion between the resin layer and the conducting layer is improved in comparison with a case where a conducting layer is formed directly on the surface of a flat resin layer.

Here, if the pattern groove having a depth-to-width ratio of 1 or above is formed, then a depth-to-width ratio of 1 or above can be achieved for the wiring pattern, and therefore low impedance can be achieved in the wiring.

Preferably, the step of photocatalyst particle exposure includes the step of pressing a molding member having a projecting section corresponding to substantially the same pattern as the wiring pattern, against a wiring pattern forming surface of the resin layer, to form the pattern groove corresponding to the projecting section, in the resin layer.

According to this aspect of the present invention, the pattern groove formed in the resin layer is determined by the shape of the projecting section formed in the molding member, and therefore, it is possible to form the pattern groove of uniform depth over the whole surface of the resin layer. The projecting height of the projecting section from the resin layer is sufficient for the pattern groove to be formed in the resin layer. Furthermore, a wide variety of shapes, such as a square shape or other rectangular shape, a hemispherical shape, or the like, may be envisaged for the shape of the projecting section, in other words, the cross-sectional shape of the projecting section perpendicular to the direction in which the pattern groove is formed.

Preferably, the step of photocatalyst particle exposure includes the step of irradiating radiation onto the pattern groove by causing the radiation to pass through the molding member while the molding member comprising a radiation non-transmission portion in which the projection sections are not formed and which has been subjected to a radiation non-transmission process is pressed against the resin layer.

Here, the section of the molding member (the radiation non-transmission portion) where the projecting section is not formed is a section other than a section where pressure is applied to the resin layer in order to form the pattern groove in the resin layer, in other words, a section of the molding member other than the projecting section (including a recess section). The section of the molding member where the projecting section is not formed is positioned facing a section of the surface of the resin layer where the pattern groove is not to be formed, when the molding member is pressed against the resin layer, and it prevent radiation from being irradiated onto a section of the resin layer other than the pattern groove forming section, when radiation passes through the molding member. Therefore, the photocatalyst particles are not exposed in a section other than the pattern groove forming section, and hence it is possible to form the highly accurate pattern groove according to a desired wiring pattern.

Moreover, since the pattern groove formation step described above and the pattern groove exposure step described above can be carried out almost simultaneously, then the manufacturing process can be simplified.

Here, the radiation non-transmission processing may be carried out on a section other than the pattern groove forming section on the surface of the resin layer; however, this requires the aforementioned processing to be carried out so as to avoid the pattern groove, and hence the processing work becomes complicated. Therefore, it is desirable that the radiation non-transmission processing be carried out onto a section of the molding member where the projecting section is not formed, as in the present invention.

Preferably, the radiation non-transmission process involves a masking process applied to the radiation non-transmission portion.

According to this aspect of the present invention, the radiation non-transmission processing involves masking applied to a section where the projecting section is not formed, and therefore, a member of a similar material to a mask which does not transmit radiation may be deposited or applied to the section where the projecting section is not formed, and it is not necessary to use a special mold having a structure comprising a layer having a masking effect, for example.

Preferably, the step of photocatalyst particle exposure includes the step of removing a part of the resin layer by irradiating a laser in the shape of the wiring pattern to expose the photocatalyst particles at the surface of the resin layer.

According to this aspect of the invention, the photocatalyst particle exposure step includes a step of exposing photocatalyst particles on the surface of the resin layer, by removing a part of the resin layer by irradiating a laser in the shape of a desired wiring pattern, and therefore, it is possible to obtain a wiring pattern having a sharp edge, which is beneficial for increasing the density of the wiring pattern.

In order to attain the aforementioned object, the present invention is also directed to a wiring substrate comprising: a base material formed by a resin layer containing photocatalyst particles which are exposed in a shape of a desired wiring pattern at a surface of the resin layer; a metal film precipitated onto the exposed photocatalyst particles; and a conducting layer formed on the metal film.

According to this aspect of the present invention, a resin layer containing photocatalyst particles is used, and the metal film for forming a conducting layer is precipitated onto the photocatalyst particles exposed at the surface of the resin layer. Therefore, it is possible to make the conducting layer (or the precipitated metal film) adhere densely to the resin layer in such a manner that the undulation generated in the surface of the resin layer by the exposed photocatalyst particles is compensated, and consequently, the bonding surface area between the resin layer and the conducting layer is increased, and an improvement in the adhesion between the resin layer and the conducting layer, in other words, an improvement in the bonding strength, can be expected.

If a material having a lower thermal conductivity than that of the material used for the conducting layer is contained in the metal film or the photocatalyst particles, then an effect in shielding heat from the resin layer can be expected. Accordingly, even in cases where high-temperature work, such as soldering, is carried out on top of the conducting layer, the effects of the heat caused by this high-temperature work are prevented from reaching the resin layer, which has inferior thermal resistance compared to the conducting layer.

According to the present invention, it is possible to achieve close and reliable bonding between a resin layer and a conducting layer, without using harmful substances, and hence a high-density arrangement of very fine wires can be achieved by increasing the density of the wiring pattern.

### BRIEF DESCRIPTION OF THE DRAWINGS

The nature of this invention, as well as other objects and benefits thereof, are explained in the following with reference to the accompanying drawings, wherein:

FIG. 1 is a cross-sectional diagram showing the structure of a wiring substrate according to an embodiment of the present invention;

FIGS. 2A to 2F are diagrams showing steps for manufacturing the wiring substrate shown in FIG. 1;

FIGS. 3A to 3E are diagrams showing steps for manufacturing a wiring substrate according to a second embodiment of the present invention;

FIGS. 4A to 4C are diagrams showing steps for manufacturing a wiring substrate according to a third embodiment of the present invention; and

FIGS. 5A to 5C are diagrams showing further steps for manufacturing a wiring substrate according to the third embodiment of the present invention.

### DETAILED DESCRIPTION OF THE PREFERRED EMBODIMENTS

### First Embodiment

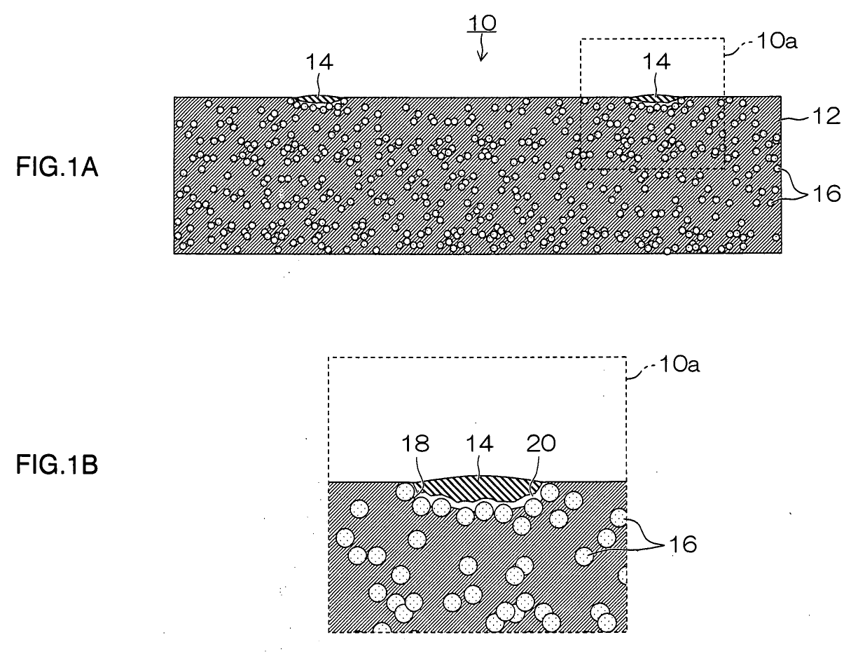

FIG. 1 is a cross-sectional diagram showing the approximate composition (three-dimensional structure) of a wiring substrate 10 relating to a wiring substrate and a method of manufacturing a wiring substrate according to the present invention. FIG. 1B is an enlarged diagram of the portion indicated by the dotted line 10a in FIG. 1A.

The wiring substrate 10 according to the present embodiment has a structure in which conducting layers 14 forming wires are formed on a resin layer 12.

The resin layer 12 has a composition in which photocatalyst particles 16 having a photocatalyst function are contained in a resin material which acts as a filler that serves to improve strength and reduce thermal expansivity. Although the details of the photocatalyst particles 16 are described hereinafter, these photocatalyst particles 16 are contained at a rate of approximately 30 to 70% (percentage by weight) with respect to the resin layer 12.

As shown in detail in FIG. 1B, a pattern 18 forming an exposed section is formed on the resin layer 12, and a conducting layer 14 is formed so as to cover this pattern 18. In this mode of conducting layers 14 formed on the resin layer 12, each conducting layer 14 has approximately the same depth as the pattern 18; however, it is not limited to a mode where it is of the same depth as the pattern. More specifically, it is possible for a portion (the surface) of each conducting layer 14 to project beyond the surface of the resin layer 12, as shown in FIG. 1B, and it is also possible for the surface of each conducting layer 14 to be level with the surface of the resin layer 12. Of course, the surface of each conducting layer 14 may also be recessed with respect to the surface of the resin layer 12. Desirably, the possibility of increase in the wiring resistance due to wiring impedance is taken into account, and therefore the thickness of the conducting layer is adjusted appropriately in consideration of this possibility. As described below, reference numeral 20 denotes a copper film used when the conducting layer 14 is formed.

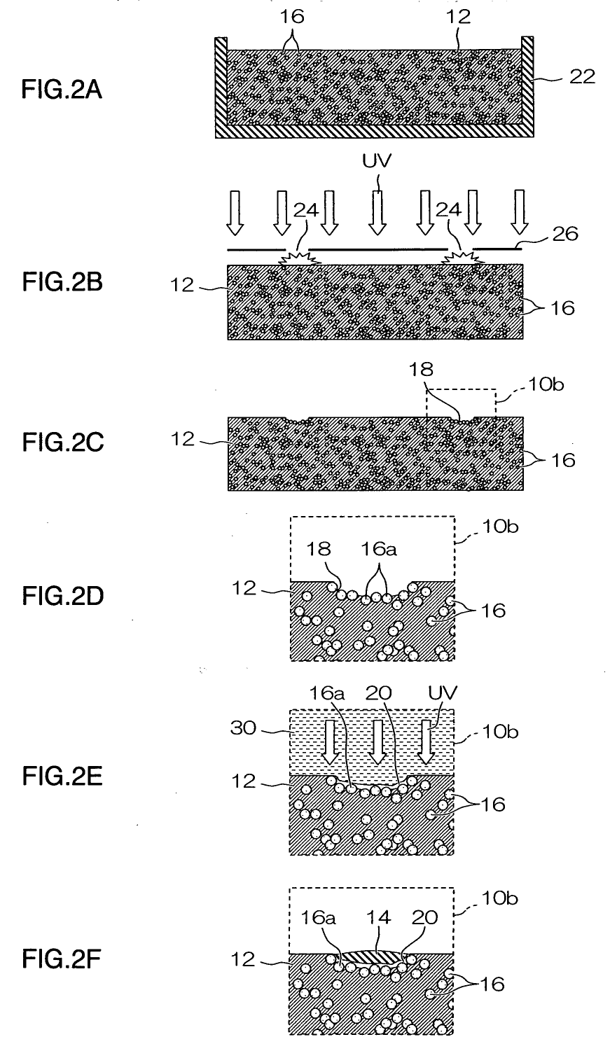

FIGS. 2A to 2F show an approximate view of steps for manufacturing a wiring substrate 10 having a composition of this kind.

As shown in FIG. 2A, firstly, in the resin layer forming step, a resin layer 12 containing photocatalyst particles 16 is formed by means of a mold 22, or the like. The thickness of the resin layer 12 is approximately 200 μm or below, and an organic material such as epoxy resin, phenol resin, polyimide, or the like, is used for the resin layer. In the present embodiment, an epoxy resin based on a general epoxy composition is used.

For the photocatalyst particles 16 contained in the resin layer 12, for example, a material can be used which is harder than the general resin material used for the resin layer 12, such as titanium oxide, zinc oxide, zirconium oxide, cadmium sulfide, potassium tantalate, cadmium selenide, and the like.

The smaller the particle size of the photocatalyst particles 16 becomes, the greater the surface area (the surface area per unit mass) becomes, and the greater the interactive effect becomes. Therefore, the higher the relative surface area, a greater reinforcing effect can be anticipated. Hence it is desirable for the particle size to be 1 μm or less. Furthermore, the shape of the photocatalyst particles 16 may be a substantially spherical shape, a cylindrical shape, a square shape, or the like; in the present application, spherically shaped particles are used. Desirably, projections, or the like, are provided on the surface of the photocatalyst particles 16 in such a manner that the surface area of the photocatalyst particles 16 is increased, because a uniform copper coating can be precipitated in the photochemical reduction precipitation step (see FIG. 2E) described hereinafter and the density of formation of the copper film can be improved.

Here, a process for the adaptation for the resin material forming the resin layer 12 is applied to the photocatalyst particles 16. Accordingly, since the resin is formed evenly about the whole perimeter of the photocatalyst particles 16, when the resin layer 12 is molded, then it is possible to prevent the photocatalyst particles 16 from being exposed at the surface of the resin layer 12.

In the photocatalyst particle exposure steps shown in FIGS. 2B to 2D, the photocatalyst particles 16 contained in the resin layer are exposed in a pattern shape. Firstly, as shown in FIG. 2B, ultraviolet light UV is irradiated via a mask 26 formed with a prescribed pattern 24. Consequently, as shown in FIG. 2C, the resin layer 12 is decomposed by causing a photocatalytic reaction only in the irradiated sections in such a manner that the photocatalyst particles 16 are exposed on the surface of the recording medium 12 in accordance with the pattern shape, thereby creating the pattern 18.

FIG. 2D is an enlarged diagram of the portion of FIG. 2C indicated by the dotted lines 10b, and it shows a mode where the photocatalyst particles 16 are exposed to form a pattern 18, following the pattern shape. The reference numeral 16a indicates a photocatalyst particle which is partially exposed at the surface of the pattern 18 in the resin layer 12.

Thereupon, in the photochemical reduction precipitation step shown in FIG. 2E, ultraviolet light UV is irradiated onto the resin layer 12 having exposed photocatalyst particles 16, while the resin layer 12 is immersed in a solution 30 containing copper ions and methanol which acts as a sacrificial reagent. As a result of the photocatalytic reaction, electrons and positive holes are generated on the surface of the photocatalyst particles 16a exposed at the surface of the resin layer 12. The copper ions in the solution incorporate the electrons and hence a copper film 20 forming a metal coating is precipitated onto the surface of each of the photocatalyst particles 16a. The recoupling of the electrons and the positive holes is prevented by the reaction of the sacrificial reagent. When the photocatalyst particles are covered with a copper film, then the ultraviolet light ceases to reach the photocatalyst particles and hence the photocatalytic reaction terminates. The thickness of the copper film 20 formed in this way is approximately several tens nm (nanometer), from the particle size of the photocatalyst particles 16 (compared with the particle size of the photocatalyst particles 16).

In the present embodiment, a composition is adopted in which copper is precipitated onto the surface of the photocatalyst particles 16a; however, provided that a material having high adhesion to the plating of the conducting layer 14 described hereinafter, is precipitated, the material is not limited to copper. For example, it is also possible to use a liquid 30 which precipitates gold, platinum, or the like, instead of copper.

In the conducting layer formation step (electroplating step) shown in FIG. 2F, a conducting layer 14 is formed by electroplating onto a resin layer 12, and a wiring pattern forming a desired circuit (a patterned conducting layer 14) is formed. In this step, the copper film 20 formed in the photochemical reduction precipitation step (FIG. 2E) serves as a power supply layer and is grown further by the electroplating process, and a conducting layer 14 is formed. In the conducting layer formation step of the present embodiment, plating is carried out by using copper as the material of the conducting layer 14 on the pattern 18 in the resin layer 12; however, instead of copper, it is also possible to carry out plating by using a conducting metal material having conductive properties, such as gold or platinum, for the conducting layer 14.

In this way, a conducting layer 14 is formed on the pattern 18 in the resin layer 12, and hence the wiring substrate 10 shown in FIG. 1 is obtained.

According to the wiring substrate 10 having the aforementioned composition, a conducting layer 14 is formed on the photocatalyst particles 16 of the resin layer 12 exposed in a pattern shape, and consequently it is possible to improve the adhesion between the resin layer 12 and the conducting layer. In other words, undulations (surface roughness or waving) occur due to the photocatalyst particles 16 which are exposed from the resin layer 12, and the conducting layer 14 (copper film 20) can adhere closely to the resin layer 12 in such a manner that it compensates the undulations (absorb the roughness of these undulations). Thereby, the contact surface area between the resin layer 12 and the conducting layer 14 is increased, and an improvement in the adhesion between the resin layer 12 and the conducting layer 14 can be expected.

In the present embodiment, a single-layer wiring substrate 10 having a conducting layer 14 formed on a resin layer 12 is described; however, it may also be applied to a double-sided substrate in which conducting layers 14 is formed on both surfaces of the resin layer 12, a flexible laminated substrate in which a plurality of single-layer wiring substrates 10 are stacked with each other, or the like.

### Second Embodiment

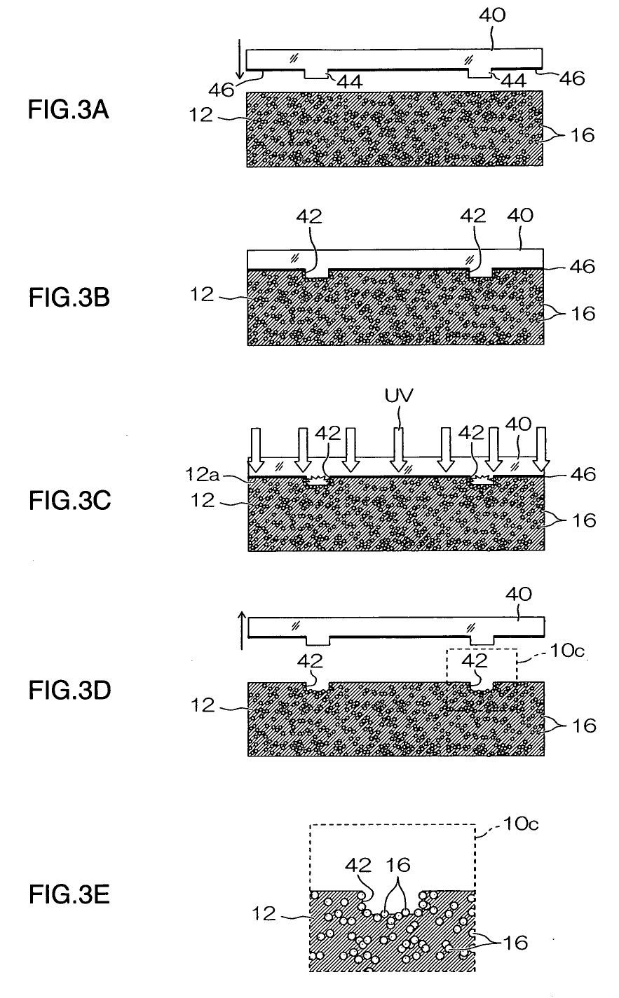

Next, a second embodiment of the present invention is described below. In the second embodiment, of the steps of manufacturing the wiring substrate, the photocatalyst particle exposure step is different to that of the first embodiment described above. In the second embodiment, items which are the same as or similar to those in the first embodiment described above are labeled with the same reference numerals and description thereof is omitted here. FIGS. 3A to 3E show schematic views of a photocatalyst particle exposure step according to the second embodiment.

In the photocatalyst particle exposure step shown in FIGS. 3A to 3E, in the pattern groove formation step shown in FIGS. 3A and 3B, pattern grooves are formed in the resin layer 12 by using a mold (stamper) 40.

This mold 40 is made from a material which transmits ultraviolet light, such as quartz, and projecting sections 44 corresponding to desired wiring patterns (in other words, projecting sections 44 having the same pattern shape as the wiring patterns) are formed previously in the mold 40. A masking process is applied to the parts of the mold 40 where the projecting sections 44 are not formed (the recess sections of the mold 40 indicated by reference numerals 46). For this masking process, processing which prevents transmission of ultraviolet light is carried out in the parts of the mold 40 where the projecting sections are not formed, and a possible mode is, for example, one where a member made of the same or similar material as the mask is attached or applied to the parts where the projecting sections are not formed.

By pressing the mold 40 having a composition of this kind against the resin layer 12, pattern grooves 42 having the same pattern shape as the wiring patterns are formed in the resin layer 12, as shown in FIG. 3B.

Thereupon, in the pattern groove exposure step shown in FIG. 3C, ultraviolet light is irradiated through the mold 40 onto the surface of the resin layer 12, in a state where the mold 40 is pressed against the resin layer 12. The ultraviolet light is irradiated inside the pattern grooves 42 in the resin layer 12 via the projecting sections of the mold 40 where the masking process sections 46 have not been formed, a photocatalytic reaction occurs in the irradiation sections, and the resin layer 12 is decomposed. The portions 12a where the pattern grooves 42 are not formed in the resin layer 12 is masked by the masking process sections 46, and hence the photocatalyst particles 16 are exposed only in the sections where the pattern grooves 42 are formed.

Accordingly, as shown in FIG. 3D, the photocatalyst particles 16 in the sections of the resin layer 12 which are irradiated with ultraviolet light are exposed at the surface of the resin layer 12, the mold 40 is then removed from the resin layer 12, and consequently, the photocatalyst particle exposure step terminates. FIG. 3E is an enlarged diagram of the portion indicated by the dotted line 10c in FIG. 3D.

Thereupon, the photochemical reduction precipitation step described above (FIG. 2E) is carried out, the conducting layer formation step (FIG. 2F) is then carried out, and consequently, a wiring substrate 10 is formed. The photochemical reduction precipitation step and the conducting layer formation step are similar to those of the first embodiment, and hence description thereof is omitted here.

Here, desirably, the resin layer 12 is pressurized by the mold 40 in FIG. 3B as described above in a state where the resin layer 12 is semi-cured, in order to form the pattern grooves 42 with high accuracy. In this case, after the photocatalyst particle exposure step, the resin layer 12 is fully cured.

The shape of the wiring pattern formed on the wiring substrate 10 shown in the present embodiment are governed by the shape (e.g., size, dimensional accuracy, and the like) of the projecting sections of the mold 40, and the degree of the flatness of the sections where the projecting sections 44 are not formed. Therefore, the possible shapes of the wiring patterns are increased, and it is possible to obtain wiring patterns having sharp edges. Accordingly, this is beneficial for achieving high density of the wiring patterns.

In particular, by adopting a conducting layer 14 patterned by using a mold 40 in this way (see FIG. 1), it is possible to increase the freedom of selection of the shape and dimensions (for example, the aspect ratio) of the conducting layer 14, and the freedom of selection of the resin material used as the resin layer 12. It is also possible to reduce the number of manufacturing steps. Consequently, if the aspect ratio of the conducting layer 14 (the ratio of the thickness of the conducting layer 14 to the width of the conducting layer 14 (“the thickness of the conducting layer 14”/“the width of the conducting layer 14”)) is one or greater, for example, then it is possible to achieve a wiring substrate 10 based on the reduction in the resistance of the wiring patterns (reduction of impedance), and it is also possible to achieve yet higher density in the wiring patterns.

In the present embodiment, a mode is described in which pattern grooves 42 having a substantially square cross-sectional shape are formed, and the pattern grooves may also have a substantially hemispherical shape (cross-sectional shape) or another shape (cross-sectional shape).

### Third Embodiment

Next, a third embodiment of the present invention is described below. In the third embodiment, items which are the same as or similar to those in the first embodiment or second embodiment described above are labeled with the same reference numerals and description thereof is omitted here.

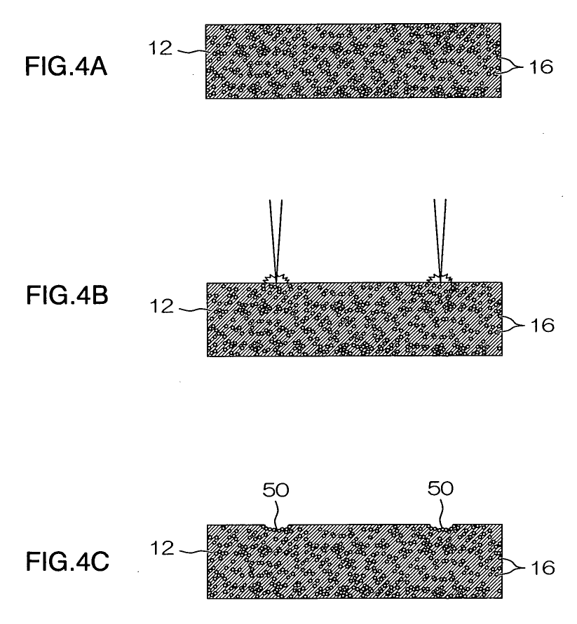

In the photocatalyst particle exposure step shown in FIGS. 4A to 4C, the photocatalyst particles 16 are exposed by means of a photocatalytic reaction based on irradiation of laser light. In other words, a laser is irradiated in a pattern shape on the resin layer 12 as shown in FIG. 4B. After that, as shown in FIG. 4C, the resin layer 12 is removed by a photocatalytic reaction using irradiation of laser light, thereby patterns 50 being formed, and at the same time, the photocatalyst particles 16 in the sections of the resin layer 12 irradiated with laser light become exposed at the surface of the resin layer 12. Since the patterns 50 are formed by laser light, it is possible to obtain wiring patterns with sharp edges, which is beneficial for achieving high density of the wiring patterns.

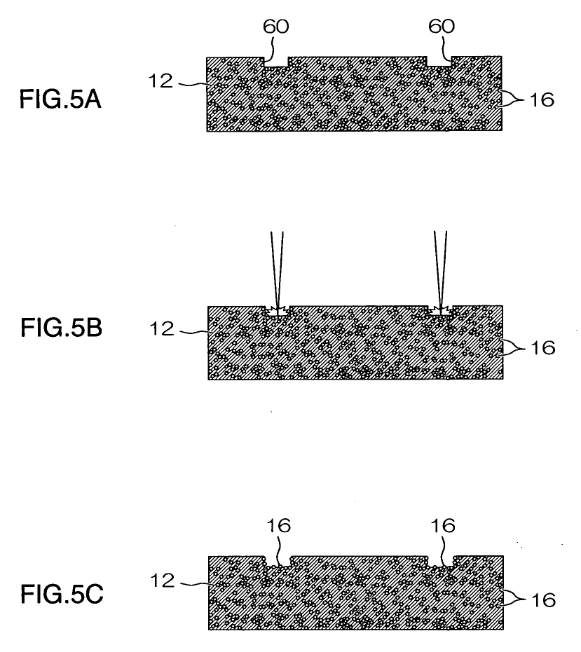

In a separate embodiment related to this, in the photocatalyst particle exposure step shown in FIGS. 5A to 5C, pattern grooves 60 are formed previously in a resin layer 12 by using a mold, or the like, as shown in FIG. 5A, and laser light is then irradiated into these pattern grooves 60 (FIG. 5B). Thereby, as shown in FIG. 5C, it is possible to expose the photocatalyst particles 16 accurately inside the pattern grooves 60 on the resin layer 12.

As the wavelength of the laser used in the present embodiment, a wavelength which allows removal of the resin layer is adopted, and therefore, it is desirable to use an excimer laser (with a wavelength of 0.15 μm), a CO₂ laser (with a wavelength of 10.6 μm), or the like.

This photocatalyst particle exposure step based on a photocatalytic reaction with the irradiation of laser light can also be used in the photocatalyst particle exposure step according to the first and second embodiments, described above.

### APPLICATION EXAMPLE

The wiring substrate according to the first to third embodiments described above is used as a drive signal transmission wiring member for sending drive signals to energy generating elements (piezoelectric elements), as used in an inkjet head (print head) mounted in an inkjet recording apparatus, for example.

A general inkjet recording apparatus comprises nozzles in an inkjet head, pressure chambers which have ink supply ports and are connected to the nozzles, and piezoelectric elements which are provided via a pressure plate forming a wall of the pressure chambers. The piezoelectric elements are connected to multiple-layer wiring members (a flexible multiple-layer substrate) having a resin layer on which a conducting layer is patterned, and drive signals are supplied via these wiring members to the piezoelectric elements, from a control system which generates drive signals sent to the piezoelectric elements (for example, a drive signal generating unit such as a head driver).

By applying a wiring substrate according to the present invention to wiring of a control system of an inkjet recording apparatus having this composition, or the like, it is possible to achieve increased density of the wiring pattern, and hence a compact inkjet recording apparatus can be achieved.

It should be understood that there is no intention to limit the invention to the specific forms disclosed, but on the contrary, the invention is to cover all modifications, alternate constructions and equivalents falling within the spirit and scope of the invention as expressed in the appended claims.

What is claimed is:

1. A method of manufacturing a wiring substrate comprising the steps of:
performing a pattern exposure of a resin layer containing photocatalyst particles, in a shape of a desired wiring pattern so that the photocatalyst particles are exposed at a surface of the resin layer;
performing irradiation of radiation to the resin layer having the exposed photocatalyst particles while the resin layer having the exposed photocatalyst particles is immersed in an aqueous solution of a metallic salt so that a photochemical reduction and precipitating of a metal film onto the exposed photocatalyst particles are performed; and
forming a conducting layer on the metal film.

2. The method of manufacturing a wiring substrate as defined in claim 1, wherein the step of photocatalyst particle exposure includes the steps of:
forming a pattern groove corresponding to substantially the same pattern as the wiring pattern, in the resin layer; and
exposing the photocatalyst particles at a surface of an inner wall of the pattern groove.

3. The method of manufacturing a wiring substrate as defined in claim 2, wherein the step of photocatalyst particle exposure includes the step of pressing a molding member having a projecting section corresponding to substantially the same pattern as the wiring pattern, against a wiring pattern forming surface of the resin layer, to form the pattern groove corresponding to the projecting section, in the resin layer.

4. The method of manufacturing a wiring substrate as defined in claim 3, wherein the step of photocatalyst particle exposure includes the step of irradiating radiation onto the pattern groove by causing the radiation to pass through the molding member while the molding member comprising a radiation non-transmission portion in which the projection sections are not formed and which has been subjected to a radiation non-transmission process is pressed against the resin layer.

5. The method of manufacturing a wiring substrate as defined in claim 4, wherein the radiation non-transmission process involves a masking process applied to the radiation non-transmission portion.

6. The method of manufacturing a wiring substrate as defined in claim 1, wherein the step of photocatalyst particle exposure includes the step of removing a part of the resin layer by irradiating a laser in the shape of the wiring pattern to expose the photocatalyst particles at the surface of the resin layer.

7. A wiring substrate comprising:
a base material formed by a resin layer containing photocatalyst particles which are exposed in a shape of a desired wiring pattern at a surface of the resin layer;
a metal film precipitated onto the exposed photocatalyst particles; and
a conducting layer formed on the metal film.
